(19) United States
(12) Patent Application Publication
(10) Pub. No.: US 2024/0003990 A1
(43) Pub. Date: Jan. 4, 2024

(54) MAGNETIC SENSOR

(71) Applicant: Panasonic Intellectual Property Management Co., Ltd., Osaka (JP)

(72) Inventors: Kazuhiro KANDA, Fukui (JP); Masahiko OHBAYASHI, Osaka (JP); Yuki OHYAMA, Fukui (JP); Hideyuki TANIGAWA, Osaka (JP); Masataka TAGAWA, Osaka (JP)

(21) Appl. No.: 18/252,151

(22) PCT Filed: Nov. 16, 2021
(86) PCT No.: PCT/JP2021/042084

§ 371 Date: May 8, 2023

Related U.S. Application Data
(60) Provisional application No. 63/117,154, filed on Nov. 23, 2020.

(30) Foreign Application Priority Data
Feb. 16, 2021 (JP) 2021-022904

(51) Int. Cl. G01R 33/00; G01R 33/09

(52) U.S. Cl. CPC G01R 33/0052; G01R 33/093; G01R 33/0005

(57) ABSTRACT

A magnetic sensor according to the present disclosure includes a supporting substrate, a glazing layer, and a magnetoresistive layer. The glazing layer is formed on the supporting substrate. The magnetoresistive layer is formed on the glazing layer. When viewed in plan in a thickness direction defined for the supporting substrate, an outer edge of the magnetoresistive layer is located inside an outer edge of the supporting substrate.

### TECHNICAL FIELD

The present disclosure generally relates to a magnetic sensor, and more particularly relates to a magnetic sensor including a magnetoresistive layer.

### BACKGROUND ART

Patent Literature 1 discloses a ferromagnetic magnetoresistive element (magnetic sensor) including a glazed alumina substrate (supporting substrate). In the ferromagnetic magnetoresistive element of Patent Literature 1, a ferromagnetic magnetoresistive film pattern (magnetoresistive layer) is formed on the glazed alumina substrate. Part of the ferromagnetic magnetoresistive film pattern is extended, as an extended electrode, to an end portion of the glazed alumina substrate.

In the magnetic sensor of Patent Literature 1, the ferromagnetic magnetoresistive film pattern is extended to the end portion of the glazed alumina substrate as described above. Thus, applying either mechanical impact or thermal stress to the end portion of the glazed alumina substrate when cutting off the glazed alumina substrate by dicing or laser cutting, for example, would cause the ferromagnetic magnetoresistive film pattern to peel off significantly or come to have a decreased degree of adhesion.

### CITATION LIST

### Patent Literature

Patent Literature 1: JP H05-75180 A

### SUMMARY OF INVENTION

It is therefore an object of the present disclosure to provide a magnetic sensor which may reduce an adverse effect on a magnetoresistive layer when its supporting substrate is cut off.

A magnetic sensor according to an aspect of the present disclosure includes a supporting substrate, a glazing layer, and a magnetoresistive layer. The glazing layer is formed on the supporting substrate. The magnetoresistive layer is formed on the glazing layer. When viewed in plan in a thickness direction defined for the supporting substrate, an outer edge of the magnetoresistive layer is located inside an outer edge of the supporting substrate.

### BRIEF DESCRIPTION OF DRAWINGS

FIG. 1 is a perspective view illustrating the appearance of a magnetic sensor according to an embodiment;

FIG. 2A is a cross-sectional view of the magnetic sensor as taken along a plane X-X shown in FIG. 1;

FIG. 2B is an enlarged view of a main part thereof shown in FIG. 2A;

FIG. 3 schematically illustrates a configuration for a detection target for the magnetic sensor;

FIG. 4 is a schematic circuit diagram of the magnetic sensor;

FIG. 5 illustrates an exemplary arrangement of magnetoresistance pattern portions, wiring pattern portions, and terminal pattern portions of the magnetic sensor;

FIG. 6A is a graph showing a first characteristic of the magnetic sensor;

FIG. 6B is a graph showing the first characteristic of a magnetic sensor according to a comparative example;

FIG. 7A is a graph showing a second characteristic of the magnetic sensor according to the exemplary embodiment;

FIG. 7B is a graph showing the second characteristic of the magnetic sensor according to the comparative example; and

FIG. 8 is an enlarged view of a main part of a magnetic sensor according to a first comparative example for the exemplary embodiment.

### DESCRIPTION OF EMBODIMENTS

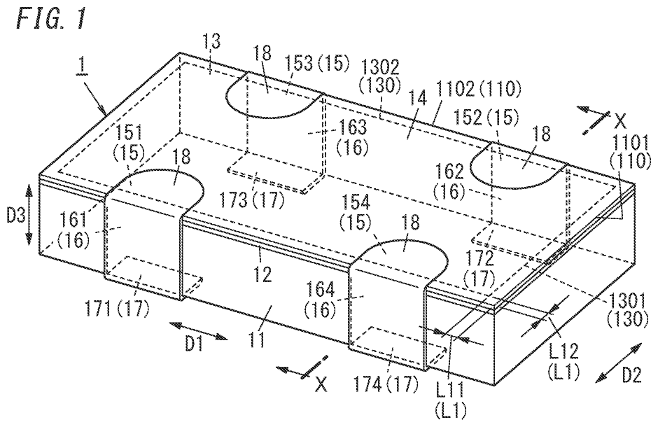

A magnetic sensor 1 according to an exemplary embodiment will be described with reference to FIGS. 1-8. FIGS. 1-3 and FIGS. 5 and 8 to be referred to in the following description of embodiments and their variations are all schematic representations. Thus, the ratio of the dimensions (including thicknesses) of respective constituent elements illustrated on the drawings does not always reflect their actual dimensional ratio.

### First Embodiment

### (1) Overview

First, an overview of a magnetic sensor 1 according to an exemplary embodiment will be described with reference to FIGS. 1-3.

The magnetic sensor 1 detects the position of a detection target 2 using magnetism. The magnetic sensor 1 may be used as, for example, a position sensor such as a linear encoder or a rotary encoder. More specifically, the magnetic sensor 1 may be used as, for example, a position sensor (encoder) for detecting, for example, the position of a camera lens driven by a motor (such as a linear motor or a rotary motor). Alternatively, the magnetic sensor 1 may also be used as, for example, a position sensor for detecting the position of a brake pedal, a brake lever, or a gear shift of an automobile. However, these are only exemplary uses of the magnetic sensor 1 and should not be construed as limiting. As used herein, the “position” to be detected by the magnetic sensor 1 is a concept encompassing both the coordinates of the detection target 2 and the rotational angle defined by the detection target 2 around a rotational axis (virtual axis) passing through the detection target 2 (i.e., the orientation of the detection target 2). That is to say, the magnetic sensor 1 detects at least one of the coordinates of the detection target 2 or the rotational angle defined by the detection target 2.

In the following description, an embodiment in which the magnetic sensor 1 is used as a linear encoder will be described as an example. The linear encoder may be an increment type or an absolute type, whichever is appropriate. In this embodiment, the magnetic sensor 1 detects the coordinates of the detection target 2.

A magnetic sensor 1 according to an exemplary embodiment includes a supporting substrate 11, a glass glazing layer (glazing layer) 12, and a magnetoresistive layer 13. The glass glazing layer 12 is formed on the supporting substrate 11. The magnetoresistive layer 13 is formed on the glass glazing layer 12. When viewed in plan in a thickness direction (third direction D3) defined for the supporting substrate 11, outer edges 130 of the magnetoresistive layer 13 are located inside outer edges 110 of the supporting substrate 11.

In the magnetic sensor 1 according to the exemplary embodiment, when viewed in plan in the third direction D3 as a thickness direction for the supporting substrate 11, the outer edges 130 of the magnetoresistive layer 13 are located inside the outer edges 110 of the supporting substrate 11. This reduces, when cutting off the supporting substrate 11 by dicing or laser cutting, the chances of transmitting mechanical impact or thermal stress to the outer edges 130 of the magnetoresistive layer 13. This reduces the chances of the magnetoresistive layer 13 peeling off from the glass glazing layer 12 or causing a decrease in adhesion between the glass glazing layer 12 and the magnetoresistive layer 13. That is to say, the magnetic sensor 1 according to this embodiment may reduce an adverse effect on the magnetoresistive layer 13 when the supporting substrate 11 is cut off.

### (2) Details

Next, the magnetic sensor 1 according to this embodiment will be described in further detail with reference to FIGS. 1-5.

(2.1) Structure of Magnetic Sensor

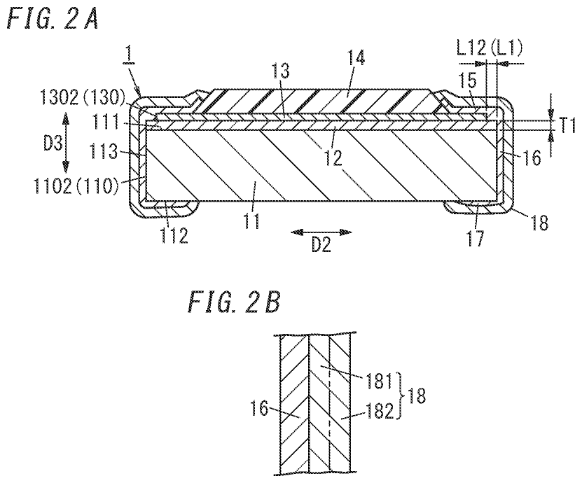

First, the structure of the magnetic sensor 1 according to this embodiment will be described with reference to FIGS. 1, 2A, and 2B.

The magnetic sensor 1 according to this embodiment is formed in the shape of a rectangular parallelepiped elongate in the first direction D1 as shown in FIGS. 1 and 2A. In the following description, the first direction D1 is defined by the longitudinal axis (i.e., length) of the magnetic sensor 1, a second direction D2 is defined by the latitudinal axis (i.e., width) of the magnetic sensor 1, and a third direction D3 is defined by the thickness of the magnetic sensor 1. However, these directions should not be construed as limiting the direction in which the magnetic sensor 1 should be used. Also, the arrows indicating these directions D1, D2, and D3 on the drawings are shown there only for illustrative purposes and are insubstantial ones. In this embodiment, the first direction D1 is a direction in which the magnetic sensor 1 moves with respect to the detection target 2. In this embodiment, the first direction D1, the second direction D2, and the third direction D3 intersect with each other at right angles.

The magnetic sensor 1 according to this embodiment includes a supporting substrate 11, a glass glazing layer (glazing layer) 12, and a magnetoresistive layer 13, as shown in FIGS. 1 and 2A. In addition, the magnetic sensor 1 according to this embodiment further includes a protective coating 14, a plurality of (e.g., four) upper surface electrodes 15, a plurality of (e.g., four) end face electrodes 16, a plurality of (e.g., four) lower surface electrodes (backside electrodes) 17, and a plurality of (e.g., four) plating layers 18. The plurality of upper surface electrodes 15, the plurality of end face electrodes 16, and the plurality of lower surface electrodes 17 correspond one to one to each other.

The supporting substrate 11 may be a ceramic substrate, for example. A material for the ceramic substrate may be, for example, sintered alumina, of which the content of alumina is equal to or greater than 96%. The supporting substrate 11 is formed in the shape of a rectangular plate which is elongate in the first direction D1 defined by the longitudinal axis of the magnetic sensor 1 when viewed in the third direction D3 defined by the thickness of the magnetic sensor 1. As shown in FIG. 2A, the supporting substrate 11 has a first principal surface 111, a second principal surface 112, and outer peripheral surfaces 113. Each of the first principal surface 111 and the second principal surface 112 is a planar surface aligned with both the first direction D1 and the second direction D2. The first principal surface 111 and the second principal surface 112 face each other in the third direction D3 that is the thickness direction for the supporting substrate 11. The outer peripheral surfaces 113 are planar surfaces aligned with the third direction D3. The outer peripheral surfaces 113 connect the first principal surface 111 and the second principal surface 112 to each other.

The glass glazing layer (glazing layer) 12 may contain, for example, silicon dioxide as a main component thereof. The glass glazing layer 12 is formed on the first principal surface 111 of the supporting substrate 11. Specifically, the glass glazing layer 12 is formed over the entire first principal surface 111 of the supporting substrate 11. The glass glazing layer 12 is formed in the shape of a rectangular layer which is elongate in the first direction D1 when viewed in the third direction D3. The glass glazing layer 12 may have a thickness T1 (refer to FIG. 2A) equal to or greater than 10 μm and equal to or less than 50 μm, for example. In the magnetic sensor 1 according to this embodiment, the glass glazing layer 12 makes the planar surface, on which the magnetoresistive layer 13 is formed, sufficiently smooth. Note that the glass glazing layer 12 only needs to be provided in a region where the plurality of magnetoresistance pattern portions 131-134 (to be described later) are arranged. Optionally, the glass glazing layer 12 may include a lead oxide.

The magnetoresistive layer 13 is formed on the glass glazing layer 12 as shown in FIG. 2A. The magnetoresistive layer 13 includes a plurality of first layers and a plurality of second layers. Each of the plurality of first layers is a magnetic layer and may contain, for example, an NiFeCo alloy. Each of the plurality of second layers is a non-magnetic layer and may contain, for example, a Cu alloy. The plurality of first layers and the plurality of second layers are alternately stacked one on top of another on the glass glazing layer 12. In the magnetic sensor 1 according to this embodiment, a giant magnetoresistive (GMR) film is formed by the magnetoresistive layer 13. The number of the first layers provided may be the same as, or different from, the number of the second layers provided, whichever is appropriate.

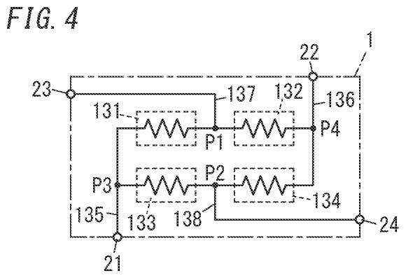

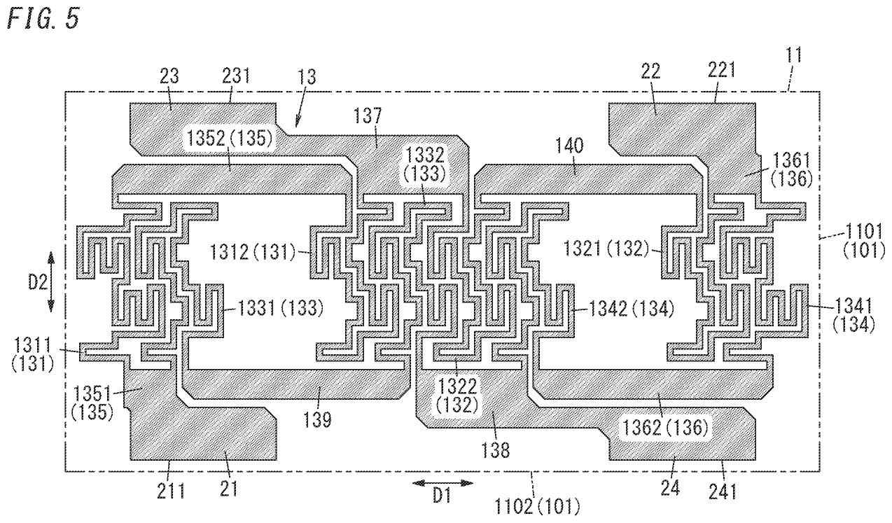

The protective coating 14 is a coating for protecting the magnetoresistive layer 13. A material for the protective coating 14 may be an epoxy resin, for example. The protective coating 14 is formed over the glass glazing layer 12 to cover the magnetoresistive layer 13 partially. In the magnetic sensor 1 according to this embodiment, a power supply terminal 21 and a ground terminal 22 (to be described later) and a first output terminal 23 and a second output terminal 24 (refer to FIGS. 4 and 5) are each connected to any of the plurality of upper surface electrodes 15. Thus, the protective coating 14 is provided to cover the magnetoresistive layer 13 entirely but at least the power supply terminal 21, the ground terminal 22, the first output terminal 23, and the second output terminal 24.

The plurality of upper surface electrodes 15 are formed on the first principal surface 111 (refer to FIG. 2A) of the supporting substrate 11 as shown in FIG. 1. A material for the plurality of upper surface electrodes 15 may be, for example, a CuNi (copper-nickel) based alloy. The plurality of upper surface electrodes 15 includes a first upper surface electrode 151, a second upper surface electrode 152, a third upper surface electrode 153, and a fourth upper surface electrode 154. Each of the plurality of upper surface electrodes 15 is connected to any of the power supply terminal 21, the ground terminal 22, the first output terminal 23, or the second output terminal 24 in the magnetoresistive layer 13. More specifically, among the plurality of upper surface electrodes 15, the first upper surface electrode 151 is connected to the power supply terminal 21. The second upper surface electrode 152 is connected to the ground terminal 22. Also, among the plurality of upper surface electrodes 15, the third upper surface electrode 153 is connected to the first output terminal 23. The fourth upper surface electrode 154 is connected to the second output terminal 24. The plurality of upper surface electrodes 15 may be, for example, a sputtered film formed by sputtering.

The plurality of end face electrodes 16 is formed to cover two outer peripheral surfaces 113 (refer to FIG. 2A), which are aligned with the longitudinal axis of the supporting substrate 11, along the longitudinal axis of the supporting substrate 11 (i.e., in the first direction D1) as shown in FIG. 1. A material for the plurality of end face electrodes 16 may be, for example, a CuNi (copper-nickel) based alloy. The plurality of end face electrodes 16 includes a first end face electrode 161, a second end face electrode 162, a third end face electrode 163, and a fourth end face electrode 164. The plurality of end face electrodes 16 correspond one to one to the plurality of upper surface electrodes 15 as described above. More specifically, the first end face electrode 161 corresponds to, and is connected to, the first upper surface electrode 151. The second end face electrode 162 corresponds to, and is connected to, the second upper surface electrode 152. The third end face electrode 163 corresponds to, and is connected to, the third upper surface electrode 153. The fourth end face electrode 164 corresponds to, and is connected to, the fourth upper surface electrode 154. The plurality of end face electrodes 16 may be, for example, a sputtered film formed by sputtering.

The plurality of lower surface electrodes 17 is formed on the second principal surface 112 (refer to FIG. 2A) of the supporting substrate 11 as shown in FIG. 1. A material for the plurality of lower surface electrodes 17 may be, for example, a CuNi (copper-nickel) based alloy. The plurality of lower surface electrodes 17 includes a first lower surface electrode 171, a second lower surface electrode 172, a third lower surface electrode 173, and a fourth lower surface electrode 174. The plurality of lower surface electrodes 17 correspond one to one to the plurality of upper surface electrodes 15 and the plurality of end face electrodes 16 as described above. More specifically, the first lower surface electrode 171 corresponds to the first upper surface electrode 151 and the first end face electrode 161 and is connected to the first end face electrode 161. The second lower surface electrode 172 corresponds to the second upper surface electrode 152 and the second end face electrode 162 and is connected to the second end face electrode 162. The third lower surface electrode 173 corresponds to the third upper surface electrode 153 and the third end face electrode 163 and is connected to the third end face electrode 163. The fourth lower surface electrode 174 corresponds to the fourth upper surface electrode 154 and the fourth end face electrode 164 and is connected to the fourth end face electrode 164. The plurality of lower surface electrodes 17 may be, for example, a sputtered film formed by sputtering.

In the magnetic sensor 1 according to this embodiment, the first upper surface electrode 151, the first end face electrode 161, and the first lower surface electrode 171 are formed in a U-shape when viewed in the first direction D1. The second upper surface electrode 152, the second end face electrode 162, and the second lower surface electrode 172 are formed in a U-shape when viewed in the first direction D1. The third upper surface electrode 153, the third end face electrode 163, and the third lower surface electrode 173 are formed in a U-shape when viewed in the first direction D1. The fourth upper surface electrode 154, the fourth end face electrode 164, and the fourth lower surface electrode 174 are formed in a U-shape when viewed in the first direction D1. That is to say, in the magnetic sensor 1 according to this embodiment, the upper surface electrodes 15, the end face electrodes 16, and the lower surface electrodes 17 are electrically connected to the magnetoresistive layer 13 and formed across the first principal surface 111, outer peripheral surfaces 113, and second principal surface 112 of the supporting substrate 11. In the magnetic sensor 1 according to this embodiment, electrodes are formed by the upper surface electrodes 15, the end face electrodes 16, and the lower surface electrodes 17.

The magnetic sensor 1 according to this embodiment may be connected to a mount board, on which the magnetic sensor 1 is going to be mounted, via the plurality of lower surface electrodes 17.

Each of the plurality of plating layers 18 is formed to cover a corresponding one of the plurality of upper surface electrodes 15, a corresponding one of the plurality of end face electrodes 16, and a corresponding one of the plurality of lower surface electrodes 17 as shown in FIG. 1. That is to say, each of the plurality of plating layers 18 is formed in a U-shape when viewed in the first direction D1. Each of the plurality of plating layers 18 includes an electroplated copper layer 181 and an electroplated tin layer 182 as shown in FIG. 2B. That is to say, each of the plurality of plating layers 18 is a non-magnetic plating layer. In the example shown in FIG. 2B, the electroplated copper layer 181 and the electroplated tin layer 182 are stacked one on top of the other such that the electroplated copper layer 181 is located inside (i.e., adjacent to the electrodes) and the electroplated tin layer 182 is located outside (i.e., opposite from the electrodes with respect to the electroplated copper layer 181). Each of the plurality of plating layers 18 is in contact with the protective coating 14 as shown in FIG. 2A. Alternatively, the plating layers 18 may include an electroplated gold layer or an electroless plated gold layer instead of the electroplated tin layer 182.

(2.2) Structure of Detection Target

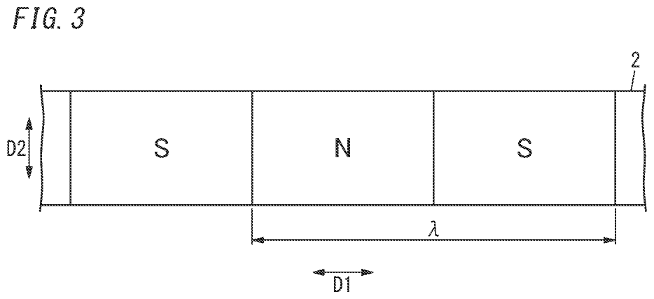

Next, the structure of the detection target 2 will be described with reference to FIG. 3.

The detection target 2 may be a magnetic scale, for example. The detection target 2 is formed in the shape of a plate which is elongate in the first direction D1 as shown in FIG. 3. The detection target 2 faces the magnetic sensor 1 in the third direction D3 (i.e., the direction perpendicular to the paper sheet on which FIG. 3 is drawn).

The detection target 2 includes a plurality of magnetic poles. The plurality of magnetic poles are arranged in the first direction D1. The plurality of magnetic poles includes one or more N poles and one or more S poles. The plurality of magnetic poles are arranged such that the one or more S poles and the one or more N poles are alternately arranged in the first direction D1. Each magnetic pole may be, for example, a ferrite magnet or a neodymium magnet. The detection target 2 includes a plurality of ferrite magnets or a plurality of neodymium magnets which are arranged in the first direction D1. The detection target 2 is magnetized in the first direction D1 in a cycle of magnetization 2 as shown in FIG. 3.

(2.3) Circuit Configuration for Magnetic Sensor

Next, a circuit configuration for the magnetic sensor 1 according to this embodiment will be described with reference to FIG. 4.

The magnetic sensor 1 according to this embodiment includes a plurality of (e.g., four) magnetoresistance pattern portions 131-134, a first wiring pattern portion 135, a second wiring pattern portion 136, a third wiring pattern portion 137, a fourth wiring pattern portion 138, a fifth wiring pattern portion 139 (refer to FIG. 5), and a sixth wiring pattern portion 140 (refer to FIG. 5) as shown in FIG. 4. In addition, the magnetic sensor 1 according to this embodiment further includes the power supply terminal 21, the ground terminal 22, the first output terminal 23, and the second output terminal 24. The magnetic sensor 1 according to this embodiment includes four magnetoresistance pattern portions 131-134 as the plurality of magnetoresistance pattern portions 131-134. The four magnetoresistance pattern portions 131-134 consist of a first magnetoresistance pattern portion 131, a second magnetoresistance pattern portion 132, a third magnetoresistance pattern portion 133, and a fourth magnetoresistance pattern portion 134.

The first magnetoresistance pattern portion 131, the second magnetoresistance pattern portion 132, the third magnetoresistance pattern portion 133, and the fourth magnetoresistance pattern portion 134 form a full bridge circuit. Specifically, a series circuit of the first magnetoresistance pattern portion 131 and the second magnetoresistance pattern portion 132 and a series circuit of the third magnetoresistance pattern portion 133 and the fourth magnetoresistance pattern portion 134 are connected to each other in parallel. In other words, the plurality of magnetoresistance pattern portions 131-134 consists of the first magnetoresistance pattern portion 131 and the second magnetoresistance pattern portion 132 that are connected together in series and the third magnetoresistance pattern portion 133 and the fourth magnetoresistance pattern portion 134 that are connected together in series.

A connection node P1 between the first magnetoresistance pattern portion 131 and the second magnetoresistance pattern portion 132 is connected to the first output terminal 23 via the third wiring pattern portion 137. That is to say, the third wiring pattern portion 137 connected to the first output terminal 23 is connected to the first magnetoresistance pattern portion 131 and the second magnetoresistance pattern portion 132 that are connected together in series among the four magnetoresistance pattern portions 131-134. The other end portion, located opposite from one end portion adjacent to the second magnetoresistance pattern portion 132, of the first magnetoresistance pattern portion 131 is connected to the power supply terminal 21 via the first wiring pattern portion 135. That is to say, the first wiring pattern portion 135 is connected to the power supply terminal 21. The other end portion, located opposite from one end portion adjacent to the first magnetoresistance pattern portion 131, of the second magnetoresistance pattern portion 132 is connected to the ground terminal 22 via the second wiring pattern portion 136. That is to say, the second wiring pattern portion 136 is connected to the ground terminal 22.

A connection node P2 between the third magnetoresistance pattern portion 133 and the fourth magnetoresistance pattern portion 134 is connected to the second output terminal 24 via the fourth wiring pattern portion 138. That is to say, the fourth wiring pattern portion 138 connected to the second output terminal 24 is connected to the third magnetoresistance pattern portion 133 and the fourth magnetoresistance pattern portion 134 that are connected together in series among the four magnetoresistance pattern portions 131-134. The other end portion, located opposite from one end portion adjacent to the fourth magnetoresistance pattern portion 134, of the third magnetoresistance pattern portion 133 is connected to the power supply terminal 21 via the first wiring pattern portion 135. The other end portion, located opposite from one end portion adjacent to the third magnetoresistance pattern portion 133, of the fourth magnetoresistance pattern portion 134 is connected to the ground terminal 22 via the second wiring pattern portion 136.

That is to say, in the magnetic sensor 1 according to this embodiment, a connection node P3 between the first magnetoresistance pattern portion 131 and the third magnetoresistance pattern portion 133 is connected to the power supply terminal 21 via the first wiring pattern portion 135. In other words, the first wiring pattern portion 135 is connected to the other end portion, located opposite from the one end portion adjacent to the second magnetoresistance pattern portion 132, of the first magnetoresistance pattern portion 131 and the other end portion, located opposite from the one end portion adjacent to the fourth magnetoresistance pattern portion 134, of the third magnetoresistance pattern portion 133.

In addition, in the magnetic sensor 1 according to this embodiment, a connection node P4 between the second magnetoresistance pattern portion 132 and the fourth magnetoresistance pattern portion 134 is connected to the ground terminal 22 via the second wiring pattern portion 136. In other words, the second wiring pattern portion 136 is connected to the other end portion, located opposite from the one end portion adjacent to the first magnetoresistance pattern portion 131, of the second magnetoresistance pattern portion 132 and the other end portion, located opposite from the one end portion adjacent to the third magnetoresistance pattern portion 133, of the fourth magnetoresistance pattern portion 134.

The power supply terminal 21, the ground terminal 22, the first output terminal 23, and the second output terminal 24 correspond one to one to plurality of upper surface electrodes 15. Specifically, the power supply terminal 21 corresponds one to one to, and is connected to, the first upper surface electrode 151 out of the plurality of upper surface electrodes 15. The ground terminal 22 corresponds one to one to, and is connected to, the second upper surface electrode 152 out of the plurality of upper surface electrodes 15. The first output terminal 23 corresponds one to one to, and is connected to, the third upper surface electrode 153 out of the plurality of upper surface electrodes 15. The second output terminal 24 corresponds one to one to, and is connected to, the fourth upper surface electrode 154 out of the plurality of upper surface electrodes 15. In the following description, the power supply terminal 21, the ground terminal 22, the first output terminal 23, and the second output terminal 24 will be hereinafter collectively referred to as “terminal pattern portions 21-24.” That is to say, in this embodiment, the terminal pattern portion 21 is constituted by the power supply terminal 21. The terminal pattern portion 22 is constituted by the ground terminal 22. The terminal pattern portion 23 is constituted by the first output terminal 23. The terminal pattern portion 24 is constituted by the second output terminal 24.

(2.4) Exemplary Arrangement of Magnetoresistance Pattern Portions, Wiring Pattern Portions, and Terminals

Next, an exemplary arrangement of the plurality of magnetoresistance pattern portions 131-134, the first to sixth wiring pattern portions 135-140, and the plurality of (four) terminal pattern portions 21-24 in the magnetic sensor 1 according to this embodiment will be described with reference to FIG. 5. In FIG. 5, the plurality of magnetoresistance pattern portions 131-134, the first to sixth wiring pattern portions 135-140, and the plurality of terminal pattern portions 21-24 are shaded by dot hatching to be easily distinguished.

The plurality of magnetoresistance pattern portions 131-134 are arranged side by side in the first direction D1 defined by the longitudinal axis of the magnetic sensor 1 as shown in FIG. 5. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134 as described above.

As shown in FIG. 5, the first magnetoresistance pattern portion 131 includes a first resistance portion 1311 and a second resistance portion 1312. Each of the first resistance portion 1311 and the second resistance portion 1312 is formed in a meandering shape when viewed in the third direction D3. That is to say, each of the first resistance portion 1311 and the second resistance portion 1312 is formed in the shape of a river that meanders in the first direction D1 and the second direction D2 when viewed in the third direction D3. Each of the first resistance portion 1311 and the second resistance portion 1312 is formed in the second direction D2. That is to say, the longitudinal axis of each of the first resistance portion 1311 and the second resistance portion 1312 is aligned with the second direction D2. The first resistance portion 1311 and the second resistance portion 1312 are connected together in series. More specifically, the first resistance portion 1311 and the second resistance portion 1312 are connected together in series via a second wiring portion 1352 (to be described later) of the first wiring pattern portion 135.

As shown in FIG. 5, the second magnetoresistance pattern portion 132 includes a first resistance portion 1321 and a second resistance portion 1322. Each of the first resistance portion 1321 and the second resistance portion 1322 is formed in a meandering shape when viewed in the third direction D3. That is to say, each of the first resistance portion 1321 and the second resistance portion 1322 is formed in the shape of a river that meanders in the first direction D1 and the second direction D2 when viewed in the third direction D3. Each of the first resistance portion 1321 and the second resistance portion 1322 is formed in the second direction D2. That is to say, the longitudinal axis of each of the first resistance portion 1321 and the second resistance portion 1322 is aligned with the second direction D2. The first resistance portion 1321 and the second resistance portion 1322 are connected together in series. More specifically, the first resistance portion 1321 and the second resistance portion 1322 are connected together in series via the sixth wiring pattern portion 140.

As shown in FIG. 5, the third magnetoresistance pattern portion 133 includes a first resistance portion 1331 and a second resistance portion 1332. Each of the first resistance portion 1331 and the second resistance portion 1332 is formed in a meandering shape when viewed in the third direction D3. That is to say, each of the first resistance portion 1331 and the second resistance portion 1332 is formed in the shape of a river that meanders in the first direction D1 and the second direction D2 when viewed in the third direction D3. Each of the first resistance portion 1331 and the second resistance portion 1332 is formed in the second direction D2. That is to say, the longitudinal axis of each of the first resistance portion 1331 and the second resistance portion 1332 is aligned with the second direction D2. The first resistance portion 1331 and the second resistance portion 1332 are connected together in series. More specifically, the first resistance portion 1331 and the second resistance portion 1332 are connected together in series via the fifth wiring pattern portion 139.

As shown in FIG. 5, the fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3. That is to say, each of the first resistance portion 1341 and the second resistance portion 1342 is formed in the shape of a river that meanders in the first direction D1 and the second direction D2 when viewed in the third direction D3. Each of the first resistance portion 1341 and the second resistance portion 1342 is formed in the second direction D2. That is to say, the longitudinal axis of each of the first resistance portion 1341 and the second resistance portion 1342 is aligned with the second direction D2. The first resistance portion 1341 and the second resistance portion 1342 are connected together in series. More specifically, the first resistance portion 1341 and the second resistance portion 1342 are connected together in series via a second wiring portion 1362 (to be described later) of the second wiring pattern portion 136.

In the magnetic sensor 1 according to this embodiment, the plurality of magnetoresistance pattern portions 131-134 are arranged in the first direction D1 in the order of the first resistance portion 1311 of the first magnetoresistance pattern portion 131, the first resistance portion 1331 of the third magnetoresistance pattern portion 133, the second resistance portion 1312 of the first magnetoresistance pattern portion 131, the second resistance portion 1332 of the third magnetoresistance pattern portion 133, the second resistance portion 1322 of the second magnetoresistance pattern portion 132, the second resistance portion 1342 of the fourth magnetoresistance pattern portion 134, the first resistance portion 1321 of the second magnetoresistance pattern portion 132, and the first resistance portion 1341 of the fourth magnetoresistance pattern portion 134 from left to right as shown in FIG. 5.

In this case, in the example shown in FIG. 5, among the plurality of first resistance portions 1311, 1321, 1331, 1341 and the plurality of second resistance portions 1312, 1322, 1332, 1342, the inner resistance portions 1321, 1331, 1312, 1322, 1332, 1342 are formed in the same shape when viewed in the third direction D3. As used herein, the “inner resistance portion” refers to a resistance portion adjacent to two other resistance portions that are arranged on both sides thereof in the first direction D1. That is to say, in the example shown in FIG. 5, the first resistance portions 1321, 1331 and the second resistance portions 1312, 1322, 1332, 1342 are inner resistance portions. Also, as used herein, the “outer resistance portion” refers to a resistance portion adjacent to another resistance portion disposed on only one side thereof in the first direction D1. That is to say, in the example shown in FIG. 5, the first resistance portions 1311, 1341 are the outer resistance portions. Furthermore, as used herein, if two things “have the same shape,” this expression refers to not only a situation where the two things have exactly the same shape but also a situation where their shapes are different to the extent that variations in their resistance value in response to a change in magnetic field strength distribution may be regarded as the same behavior. Therefore, the inner resistance portions 1321, 1331, 1312, 1322, 1332, 1342 may have mutually different shapes as long as variations in their resistance value in response to a change in magnetic field strength distribution may be regarded as the same behavior.

The first wiring pattern portion 135 connects the first magnetoresistance pattern portion 131 and the terminal pattern portion (power supply terminal) 21 and also connects the third magnetoresistance pattern portion 133 and the terminal pattern portion 21 as shown in FIG. 5. The first wiring pattern portion 135 includes a first wiring portion 1351 and a second wiring portion 1352. The first wiring portion 1351 is formed in a rectangular shape when viewed in the third direction D3 and is connected to the terminal pattern portion 21 at a first end portion thereof. A second end portion of the first wiring portion 1351 is connected to a first end portion of the first resistance portion 1311 of the first magnetoresistance pattern portion 131 and a first end portion of the first resistance portion 1331 of the third magnetoresistance pattern portion 133. A second end portion of the first resistance portion 1331 of the third magnetoresistance pattern portion 133 is connected to the fifth wiring pattern portion 139. The second wiring portion 1352 is formed to be elongate in the first direction D1 when viewed in the third direction D3. The second wiring portion 1352 is connected to a second end portion of the first resistance portion 1311 of the first magnetoresistance pattern portion 131 and a first end portion of the second resistance portion 1312 of the first magnetoresistance pattern portion 131. A second end portion of the second resistance portion 1312 of the first magnetoresistance pattern portion 131 is connected to the third wiring pattern portion 137.

The second wiring pattern portion 136 connects the second magnetoresistance pattern portion 132 and the terminal pattern portion (ground terminal) 22 and also connects the fourth magnetoresistance pattern portion 134 and the terminal pattern portion 22 as shown in FIG. 5. The second wiring pattern portion 136 includes a first wiring portion 1361 and a second wiring portion 1362. The first wiring portion 1361 is formed in a rectangular shape when viewed in the third direction D3 and is connected to the terminal pattern portion 22 at a first end portion thereof. A second end portion of the first wiring portion 1361 is connected to a first end portion of the first resistance portion 1321 of the second magnetoresistance pattern portion 132 and a first end portion of the first resistance portion 1341 of the fourth magnetoresistance pattern portion 134. A second end portion of the first resistance portion 1321 of the second magnetoresistance pattern portion 132 is connected to the sixth wiring pattern portion 140. The second wiring portion 1362 is formed to be elongate in the first direction D1 when viewed in the third direction D3. The second wiring portion 1362 is connected to a second end portion of the first resistance portion 1341 of the fourth magnetoresistance pattern portion 134 and a first end portion of the second resistance portion 1342 of the fourth magnetoresistance pattern portion 134. A second end portion of the second resistance portion 1342 of the fourth magnetoresistance pattern portion 134 is connected to the fourth wiring pattern portion 138.

The third wiring pattern portion 137 connects together the first magnetoresistance pattern portion 131 and the terminal pattern portion (first output terminal) 23 and also connects together the second magnetoresistance pattern portion 132 and the terminal pattern portion 23 as shown in FIG. 5. The third wiring pattern portion 137 is formed in an L-shape when viewed in the third direction D3 and connected to the terminal pattern portion 23 at a first end portion thereof. The second end portion of the third wiring pattern portion 137 is connected to the second end portion of the second resistance portion 1312 of the first magnetoresistance pattern portion 131 and the second end portion of the second resistance portion 1322 of the second magnetoresistance pattern portion 132 as described above.

The fourth wiring pattern portion 138 connects together the third magnetoresistance pattern portion 133 and the terminal pattern portion (second output terminal) 24 and also connects together the fourth magnetoresistance pattern portion 134 and the terminal pattern portion 24 as shown in FIG. 5. The fourth wiring pattern portion 138 is formed in an L-shape when viewed in the third direction D3 and connected to the terminal pattern portion 24 at a first end portion thereof. The second end portion of the fourth wiring pattern portion 138 is connected to the second end portion of the second resistance portion 1332 of the third magnetoresistance pattern portion 133 and the second end portion of the second resistance portion 1342 of the fourth magnetoresistance pattern portion 134 as described above.

The fifth wiring pattern portion 139 is formed to be elongate in the first direction D1 when viewed in the third direction D3 as shown in FIG. 5. The fifth wiring pattern portion 139 connects together the first resistance portion 1331 and second resistance portion 1332 of the third magnetoresistance pattern portion 133. The sixth wiring pattern portion 140 is formed to be elongate in the first direction D1 when viewed in the third direction D3 as shown in FIG. 5. The sixth wiring pattern portion 140 connects together the first resistance portion 1321 and second resistance portion 1322 of the second magnetoresistance pattern portion 132.

In the magnetic sensor 1 according to this embodiment, the magnetoresistive layer 13 constitutes the plurality of magnetoresistance pattern portions 131-134, the first to sixth wiring pattern portions 135-140, and the plurality of terminal pattern portions 21-24. That is to say, in the magnetic sensor 1 according to this embodiment, the first to sixth wiring pattern portions 135-140 and the plurality of terminal pattern portions 21-24 are made of the same material as the plurality of magnetoresistance pattern portions 131-134.

In this embodiment, as the magnetic sensor 1 moves in the first direction D1 with respect to the detection target 2, for example, the strength of the magnetic field between the magnetic sensor 1 and the detection target 2 changes. In response to this change in the magnetic field strength, the resistance values of the plurality of magnetoresistance pattern portions 131-134 vary. Then, the position of the detection target 2 may be detected by detecting potentials at the first output terminal 23 and the second output terminal 24. Note that the magnetic sensor 1 and the detection target 2 may be configured to move relative to each other. Thus, the magnetic sensor 1 and the detection target 2 may also be configured such that the detection target 2 moves relative to the magnetic sensor 1.

(2.5) Arrangement of Magnetoresistive Layer

Next, a relative arrangement of the magnetoresistive layer 13 with respect to the supporting substrate 11, of which the first principal surface 111 is covered with the glass glazing layer 12, will be described with reference to FIGS. 1, 2A, and 5.

As shown in FIGS. 1 and 2A, when viewed in plan in the third direction D3 (i.e., the thickness direction defined for the supporting substrate 11), the outer edges 130 of the magnetoresistive layer 13 are located inside the outer edges 110 of the supporting substrate 11. In the example illustrated in FIG. 1, the outer edges 130 of the magnetoresistive layer 13 are located, along its entire circumference, inside the outer edges 110 of the supporting substrate 11. However, this is only an example and should not be construed as limiting. Alternatively, the outer edges 130 of the magnetoresistive layer 13 may partially overlap with the outer edges 110 of the supporting substrate 11. That is to say, the expression “the outer edges 130 of the magnetoresistive layer 13 are located inside the outer edges 110 of the supporting substrate 11” as used herein means that the outer edges 130 of the magnetoresistive layer 13 are located at least partially inside the outer edges 110 of the supporting substrate 11.

As shown in FIGS. 1 and 2A, the outer edges 130 of the magnetoresistive layer 13 are made up of two first outer edges 1301 and two second outer edges 1302. That is to say, the magnetoresistive layer 13 has the two first outer edges 1301 and the two second outer edges 1302. Each of the two first outer edges 1301 is aligned with the second direction D2. Each of the two second outer edges 1302 is aligned with the first direction D1. The magnetoresistive layer 13 is formed by the two first outer edges 1301 and the two second outer edges 1302 in the shape of a rectangle which is elongate in the first direction D1 when viewed in plan in the third direction D3.

On the other hand, the outer edges 110 of the supporting substrate 11 are made up of two first outer edges 1101 and two second outer edges 1102 as shown in FIGS. 1 and 2A. That is to say, the supporting substrate 11 has the two first outer edges 1101 and the two second outer edges 1102. Each of the two first outer edges 1101 is aligned with the second direction D2. Each of the two second outer edges 1102 is aligned with the first direction D1. The supporting substrate 11 is formed by the two first outer edges 1101 and the two second outer edges 1102 in the shape of a rectangle which is elongate in the first direction D1 when viewed in plan in the third direction D3.

As shown in FIG. 1, the distance (hereinafter referred to as a “first distance”) measured in the first direction D1 between each of the two first outer edges 1101 of the supporting substrate 11 and a corresponding one of the two first outer edges 1301 of the magnetoresistive layer 13 is L11. Also, as shown in FIGS. 1 and 2A, the distance (hereinafter referred to as a “second distance”) measured in the second direction D2 between each of the two second outer edges 1102 of the supporting substrate 11 and a corresponding one of the two second outer edges 1302 of the magnetoresistive layer 13 is L12. The first distance L11 and the second distance L12 may be the same or different, whichever is appropriate. This embodiment will be described on the supposition that the first distance L11 and the second distance L12 are the same.

In this embodiment, the ratio of the distance (i.e., the first distance L11 or the second distance L12) between the outer edges 110 of the supporting substrate 11 and the outer edges 130 of the magnetoresistive layer 13 when viewed in plan in the third direction D3 (i.e., the thickness direction defined for the supporting substrate 11) to the thickness T1 (refer to FIG. 2) of the glass glazing layer 12 is preferably equal to or greater than 0.5 and equal to or less than 3.0. The ratio of each of the first distance L11 and the second distance L12 to the thickness T1 of the glass glazing layer 12 is more preferably equal to or greater than 1.0 and equal to or less than 2.0.

The glass glazing layer 12 has a thickness T1 equal to or greater than 10 μm and equal to or less than 50 μm as described above. If the ratio of each of the first distance L11 and the second distance L12 to the thickness T1 of the glass glazing layer 12 is 0.5, then each of the first distance L11 and the second distance L12 becomes equal to or greater than 5 μm and equal to or less than 25 μm. On the other hand, if the ratio of each of the first distance L11 and the second distance L12 to the thickness T1 of the glass glazing layer 12 is 3.0, then each of the first distance L11 and the second distance L12 becomes equal to or greater than 30 μm and equal to or less than 150 μm. That is to say, if the ratio of each of the first distance L11 and the second distance L12 to the thickness T1 of the glass glazing layer 12 is equal to or greater than 0.5 and equal to or less than 3.0, then each of the first distance L11 and the second distance L12 becomes equal to or greater than 5 μm and equal to or less than 150 μm.

Furthermore, if the ratio of each of the first distance L11 and the second distance L12 to the thickness T1 of the glass glazing layer 12 is 1.0, then each of the first distance L11 and the second distance L12 becomes equal to or greater than 10 μm and equal to or less than 50 μm. Furthermore, if the ratio of each of the first distance L11 and the second distance L12 to the thickness T1 of the glass glazing layer 12 is 2.0, then each of the first distance L11 and the second distance L12 becomes equal to or greater than 20 μm and equal to or less than 100 μm. That is to say, if the ratio of each of the first distance L11 and the second distance L12 to the thickness T1 of the glass glazing layer 12 is equal to or greater than 1.0 and equal to or less than 2.0, then each of the first distance L11 and the second distance L12 becomes equal to or greater than 10 μm and equal to or less than 100 μm. In summary, each of the first distance L11 and the second distance L12 with respect to the glass glazing layer 12 is preferably equal to or greater than 5 μm and equal to or less than 150 μm. More preferably, each of the first distance L11 and the second distance L12 with respect to the glass glazing layer 12 is equal to or greater than 10 μm and equal to or less than 100 μm.

More specifically, the magnetoresistive layer 13 includes a plurality of (e.g., four) magnetoresistance pattern portions 131-134 and a plurality of (e.g., four) terminal pattern portions 21-24 as shown in FIG. 5. The plurality of terminal pattern portions 21-24 are provided to surround the plurality of magnetoresistance pattern portions 131-134. The outer edge 211 of the terminal pattern portion (power supply terminal) 21 in the second direction D2 is located inside the outer edge 110 (second outer edge 1102) of the supporting substrate 11 when viewed in plan in the third direction D3 that is the thickness direction for the supporting substrate 11. The outer edge 221 of the terminal pattern portion (ground terminal) 22 in the second direction D2 is located inside the outer edge 110 (second outer edge 1102) of the supporting substrate 11 when viewed in plan in the third direction D3 that is the thickness direction for the supporting substrate 11. The outer edge 231 of the terminal pattern portion (first output terminal) 23 in the second direction D2 is located inside the outer edge 110 (second outer edge 1102) of the supporting substrate 11 when viewed in plan in the third direction D3 that is the thickness direction for the supporting substrate 11. The outer edge 241 of the terminal pattern portion (second output terminal) 24 in the second direction D2 is located inside the outer edge 110 (second outer edge 1102) of the supporting substrate 11 when viewed in plan in the third direction D3 that is the thickness direction for the supporting substrate 11.

As described above, the outer edges 130 of the magnetoresistive layer 13 are located inside the outer edges 110 of the supporting substrate 11. This reduces, when cutting off the wafer by dicing or laser cutting into respective magnetic sensors 1 in the seventh step of the method for manufacturing the magnetic sensor 1 (to be described later), the chances of transmitting, to the magnetoresistive layer 13, the mechanical impact or thermal stress applied to the supporting substrate 11. This reduces the chances of the magnetoresistive layer 13 peeling off from the glass glazing layer 12 or causing a decrease in adhesion between the glass glazing layer 12 and the magnetoresistive layer 13. That is to say, the magnetic sensor 1 according to the exemplary embodiment may reduce an adverse effect on the magnetoresistive layer 13 when the supporting substrate 11 is cut off.

(2.6) Characteristics of Magnetic Sensor

Next, the characteristics of the magnetic sensor 1 according to this embodiment will be described in comparison with the characteristics of a magnetic sensor according to a comparative example.

(2.6.1) First Characteristic

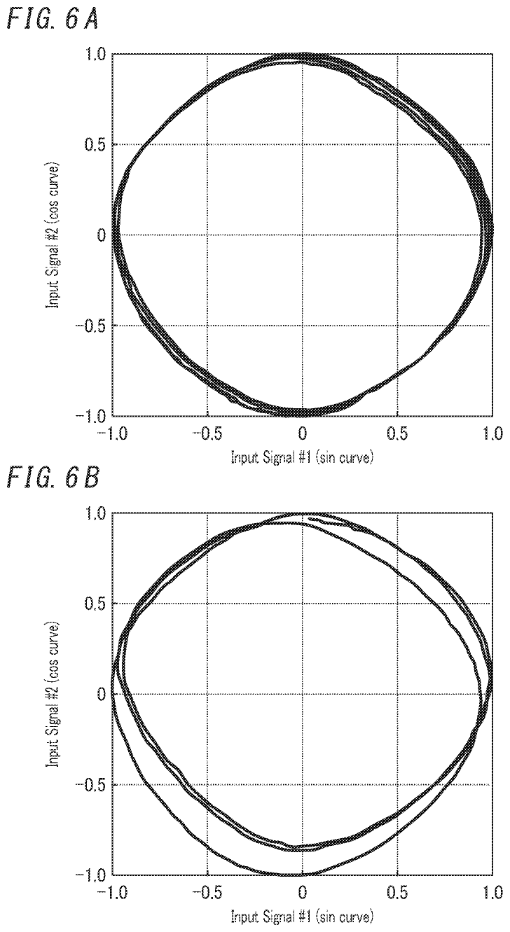

First, a first characteristic of the magnetic sensor 1 according to this embodiment will be described with reference to FIGS. 6A and 6B. In each of FIGS. 6A and 6B, the abscissa indicates an input signal #1 (i.e., an output signal of the magnetic sensor) and the ordinate indicates an input signal #2 (i.e., an output signal of the magnetic sensor). In the example shown in FIGS. 6A and 6B, the input signal #1 is a sin signal and the input signal #2 is a cos signal.

In the magnetic sensor 1 according to the exemplary embodiment, the plating layers 18 are non-magnetic plating layers including the electroplated copper layer 181 and the electroplated tin layer 182. On the other hand, in a magnetic sensor according to a comparative example, the plating layers are magnetic plating layers including an electroplated nickel layer and an electroplated tin layer.

In the magnetic sensor according to the comparative example, the plating layer proximate to the magnetoresistive layer is a magnetic plating layer, and therefore, the resistance value of the plating layer varies so significantly as to have a considerable effect on the magnetoresistive layer. As a result, the magnetic sensor according to the comparative example comes to have widely dissimilar Lissajous figures as shown in FIG. 6B.

In contrast, in the magnetic sensor 1 according to the exemplary embodiment, the plating layer 18 proximate to the magnetoresistive layer 13 is a non-magnetic layer. Thus, the resistance value does not vary in response to a change in the magnetic field strength to be caused by the detection target 2 (magnetic scale), and therefore, the output waveform is hardly affected by disturbance. As a result, the magnetic sensor 1 according to the exemplary embodiment comes to have quite similar Lissajous figures as shown in FIG. 6A.

(2.6.2) Second Characteristic

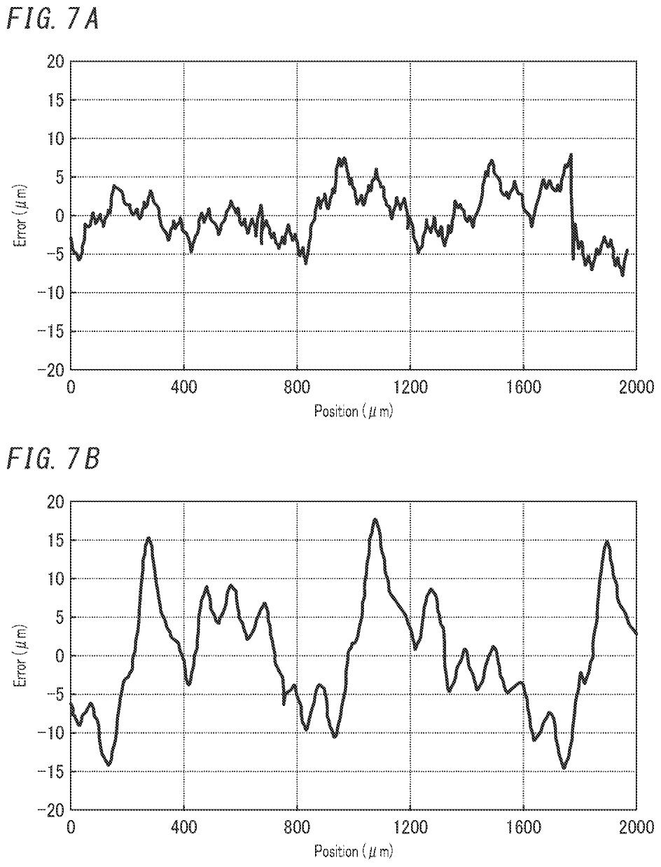

Next, a second characteristic of the magnetic sensor 1 according to the exemplary embodiment will be described with reference to FIGS. 7A and 7B. In each of FIGS. 7A and 7B, the abscissa indicates the distance (μm) from a reference position (initial position) and the ordinate indicates the detection error (μm) of the detection target 2.

In the magnetic sensor 1 according to the exemplary embodiment, the plating layers 18 are non-magnetic plating layers as described above. On the other hand, in the magnetic sensor according to a comparative example, the plating layers are magnetic plating layers.

In the magnetic sensor according to the comparative example, the detection error of the detection target 2 has a maximum value of about 15 μm on the negative side and a maximum value of about 17 μm on the positive side as shown in FIG. 7B.

On the other hand, in the magnetic sensor 1 according to the exemplary embodiment, the detection error of the detection target 2 has a maximum value of about 7 μm on the negative side and a maximum value of about 8 μm on the positive side as shown in FIG. 7A.

As can be seen, using non-magnetic plating layers as the plating layers 18 reduces the detection error of the detection target 2.

### (3) Method for Manufacturing Magnetic Sensor

Next, a method for manufacturing a magnetic sensor 1 according to this embodiment will be described.

The method for manufacturing the magnetic sensor 1 includes the following first through ninth steps.

A first step includes providing a supporting substrate 11. More specifically, the first step includes providing a wafer, which forms the basis of respective supporting substrates 11 of a plurality of magnetic sensors 1. The wafer may be a ceramic wafer, for example. A material for the ceramic wafer used as the wafer may be, for example, sintered alumina, of which the content of alumina is equal to or greater than 96%.

A second step includes forming a glass glazing layer 12 on the first principal surface of the wafer. The first principal surface of the wafer is a surface that will be the first principal surface 111 of the supporting substrate 11 in each of the plurality of magnetic sensors 1. More specifically, the second step includes forming the glass glazing layer 12 by applying a glass paste onto the first principal surface 111 of the supporting substrate 11 and then firing the glass paste.

A third step includes forming a magnetoresistive layer 13 for the plurality of magnetic sensors 1. More specifically, the third step includes forming the magnetoresistive layer 13 on the glass glazing layer 12 by sputtering, for example. In the magnetic sensor 1 according to this embodiment, the magnetoresistive layer 13 is formed as a GMR film as described above by alternately stacking a plurality of NiFeCo alloy layers (first layers) and a plurality of Cu alloy layers (second layers).

A fourth step includes forming a protective coating 14. More specifically, the fourth step includes applying an epoxy resin by screen printing onto the glass glazing layer 12 such that the magnetoresistive layer 13 is partially covered with the epoxy resin and then thermally curing the epoxy resin, thereby forming the protective coating 14. In this process step, the protective coating 14 is formed to cover the magnetoresistive layer 13 entirely but at least the power supply terminal 21, the ground terminal 22, the first output terminal 23, and the second output terminal 24.

A fifth step includes forming a plurality of upper surface electrodes 15 on the first principal surface of the wafer for each of the plurality of magnetic sensors 1. More specifically, the fifth step includes forming a copper-nickel based alloy film on the first principal surface of the wafer by sputtering, for example, thereby forming the plurality of upper surface electrodes 15 for each of the plurality of magnetic sensors 1.

A sixth step includes forming a plurality of lower surface electrodes 17 on the second principal surface of the wafer for each of the plurality of magnetic sensors 1. More specifically, the sixth step includes forming a copper-nickel based alloy film on the second principal surface of the wafer by sputtering, for example, thereby forming the plurality of lower surface electrodes 17 for each of the plurality of magnetic sensors 1. The second principal surface of the wafer is a surface that will be the second principal surface 112 of the supporting substrate 11 in each of the plurality of magnetic sensors 1.

A seventh step includes cutting off the assembly of the plurality of magnetic sensors 1 that have been formed integrally by performing the first through sixth steps into respective magnetic sensors 1. More specifically, the seventh step includes cutting off, by laser cutting or dicing, for example, the assembly of the plurality of magnetic sensors 1 that have been formed integrally into respective magnetic sensors 1.

An eighth step includes forming a plurality of end face electrodes 16 on each magnetic sensor 1 that has been cut off. More specifically, the eighth step includes forming a copper-nickel based alloy film on the outer peripheral surfaces 113 of the supporting substrate 11 by sputtering, for example, thereby forming a plurality of end face electrodes 16 on each of the plurality of magnetic sensors 1. This allows the plurality of upper surface electrodes 15 and the plurality of lower surface electrodes 17 to be connected together via the plurality of end face electrodes 16.

A ninth step includes forming plating layers 18 on each of the plurality of magnetic sensors 1. More specifically, the ninth step includes sequentially forming an electroplated copper layer 181 and an electroplated tin layer 182 with respect to each of the plurality of magnetic sensors 1.

The magnetic sensor 1 according to this embodiment may be manufactured by performing the first through ninth steps described above.

### (4) Advantages

In the magnetic sensor 1 according to the exemplary embodiment, when viewed in plan in the third direction D3 that is the thickness direction for the supporting substrate 11, the outer edges 130 of the magnetoresistive layer 13 are located inside the outer edges 110 of the supporting substrate 11. This reduces, when cutting off the supporting substrate 11 by, for example, dicing or laser cutting, the chances of transmitting mechanical impact or thermal stress to the outer edges 130 of the magnetoresistive layer 13. This reduces the chances of the magnetoresistive layer 13 peeling off from the glass glazing layer 12 or causing a decrease in adhesion between the glass glazing layer 12 and the magnetoresistive layer 13. That is to say, the magnetic sensor 1 according to the exemplary embodiment may reduce an adverse effect on the magnetoresistive layer 13 when the supporting substrate 11 is cut off. Note that the outer edges 130 of the magnetoresistive layer 13 do not have to be located in their entirety inside the outer edges 110 of the supporting substrate 11. Rather the advantages described above are achievable as long as the outer edges 130 of the magnetoresistive layer 13 is mostly located inside the outer edges 110 of the supporting substrate 11. Thus, these advantages would not diminish significantly even if the magnetoresistive layer 13 partially overlaps with the cutting line when the wafer is cut off into respective magnetic sensors 1.

In addition, in the magnetic sensor 1 according to the exemplary embodiment described above, the plating layers 18 are non-magnetic plating layers as described above. This reduces an adverse effect of the plating layers 18 on the magnetoresistive layer 13 (magnetoresistance pattern portions 131-134), thus reducing the chances of causing a detection error of the detection target 2.

Furthermore, in the magnetic sensor 1 according to this embodiment, the plating layers 18 are electroplated layers (namely, the electroplated copper layer 181 and the electroplated tin layer 182). This allows, compared to a situation where the plating layers 18 are electroless plated layers, the magnetic sensor 1 to adhere more securely to a mount board on which the magnetic sensor 1 is going to be mounted. Consequently, this contributes to increasing the connectivity of the magnetic sensor 1 to the mount board.

### (5) Variations

Note that the embodiment described above is only an exemplary one of various embodiments of the present disclosure and should not be construed as limiting. Rather, the exemplary embodiment may be readily modified in various manners depending on a design choice or any other factor without departing from the scope of the present disclosure. Next, variations of the exemplary embodiment will be enumerated one after another. Note that the variations to be described below may be adopted in combination as appropriate.

(5.1) First Variation

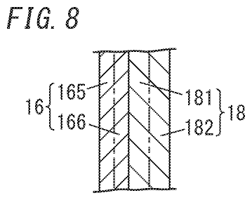

A magnetic sensor 1 according to a first variation will be described with reference to FIG. 8. In the magnetic sensor 1 according to the first variation, the electrodes (of which only an end face electrode 16 is shown in FIG. 8) each include a first metal layer 165 and a second metal layer 166, which is a difference from the magnetic sensor 1 according to the exemplary embodiment described above. In the other respects, the magnetic sensor 1 according to the first variation has the same configuration as the magnetic sensor 1 according to the exemplary embodiment described above. Thus, any constituent element of the magnetic sensor 1 according to this first variation, having the same function as a counterpart of the magnetic sensor 1 according to the embodiment described above, will be designated by the same reference numeral as that counterpart's, and description thereof will be omitted herein.

In the magnetic sensor 1 according to the first variation, the end face electrode 16 includes the first metal layer 165 and the second metal layer 166 as shown in FIG. 8. The first metal layer 165 contains, for example, either chromium or a chromium alloy. The second metal layer 166 contains, for example, either copper or a copper-nickel alloy. The chromium alloy is an alloy containing chromium as a main component thereof. The copper-nickel alloy is an alloy containing copper-nickel as a main component thereof. In the magnetic sensor 1 according to this first variation, the first metal layer 165 and the second metal layer 166 are stacked one on top of the other such that the first metal layer 165 is located inside (i.e., closer to the supporting substrate 11 than) the second metal layer 166 and that the second metal layer 166 is located outside (i.e., opposite from the supporting substrate 11 with respect to the first metal layer 165) the first metal layer 165. Note that although neither the upper surface electrodes 15 nor the lower surface electrodes 17 are illustrated in FIG. 8, the same statement applies to the upper surface electrodes 15 and the lower surface electrodes 17 as well and description thereof will be omitted herein. Stacking the first metal layer 165 and the second metal layer 166 in this manner such that the first metal layer 165 is located inside the second metal layer 166 and that the second metal layer 166 is located outside the first metal layer 165 ensures that the electrodes are electrically conductive with the magnetoresistive layer 13 while increasing the degree of adhesion of the electrodes to the underlying members (namely, the supporting substrate 11, the glass glazing layer 12, and the magnetoresistive layer 13).

Although the first metal layer 165 is provided inside and the second metal layer 166 is provided outside in the first variation, the second metal layer 166 may be provided inside and the first metal layer 165 may be provided outside.

(5.2) Other Variations

Next, other variations will be enumerated one after another.

The plurality of magnetoresistance pattern portions 131-134 do not have to have the meandering shape but may have any other shape.

In the embodiment described above, each of the magnetoresistance pattern portions 131-134 consists of two resistance portions. Alternatively, each of the magnetoresistance pattern portions 131-134 may also consist of only one resistance portion or even three or more resistance portions.

In the embodiment described above, each of the electrodes (namely, the upper surface electrodes 15, the end face electrodes 16, and the lower surface electrodes 17) is a metal layer containing a copper-nickel (CuNi) based alloy. Alternatively, each of the electrodes may also be a metal layer containing nickel chromium or a metal layer containing a nickel-chromium alloy. The nickel-chromium alloy is an alloy containing nickel chromium as a main component thereof.

In the embodiment described above, the plating layers 18 include the electroplated copper layer 181 and the electroplated tin layer 182. Alternatively, the plating layers 18 may include, for example, an electroless plated nickel-phosphorus layer and an electroplated tin layer. In that case, the electroless plated nickel-phosphorus layer may be provided inside (i.e., adjacent to the electrodes) and the electroplated tin layer may be provided outside (i.e., opposite from the electrodes with respect to the electroless plated nickel-phosphorus layer), or vice versa. Still alternatively, the plating layers 18 may also include an electroless plated nickel-phosphorus layer and either an electroplated gold layer or an electroless plated gold layer. Each of these alternative configurations improves the electrical connectivity of the magnetic sensor 1 to the mount board while reducing the chances of causing a detection error of the detection target 2.

(Aspects)

The embodiments and their variations described above are specific implementations of the following aspects of the present disclosure.

A magnetic sensor (1) according to a first aspect includes a supporting substrate (11), a glazing layer (12), and a magnetoresistive layer (13). The glazing layer (12) is formed on the supporting substrate (11). The magnetoresistive layer (13) is formed on the glazing layer (12). When viewed in plan in a thickness direction (D3) defined for the supporting substrate (11), an outer edge (130) of the magnetoresistive layer (13) is located inside an outer edge (110) of the supporting substrate (11).

This aspect reduces an adverse effect on the magnetoresistive layer (13) when the supporting substrate (11) is cut off.

In a magnetic sensor (1) according to a second aspect, which may be implemented in conjunction with the first aspect, a ratio of a distance (L1) between the outer edge (110) of the supporting substrate (11) and the outer edge (130) of the magnetoresistive layer (13) when viewed in plan in the thickness direction (D3) defined for the supporting substrate (11) to a thickness (T1) of the glazing layer (12) is equal to or greater than 0.5.

This aspect reduces an adverse effect on the magnetoresistive layer (13) when the supporting substrate (11) is cut off.

In a magnetic sensor (1) according to a third aspect, which may be implemented in conjunction with the second aspect, the ratio is equal to or less than 3.0.

This aspect contributes to downsizing the magnetic sensor (1).

In a magnetic sensor (1) according to a fourth aspect, which may be implemented in conjunction with any one of the first to third aspects, a distance (L1) between the outer edge (110) of the supporting substrate (11) and the outer edge (130) of the magnetoresistive layer (13) when viewed in plan in the thickness direction (D3) defined for the supporting substrate (11) is equal to or greater than 5 μm.

This aspect reduces an adverse effect on the magnetoresistive layer (13) when the supporting substrate (11) is cut off.

In a magnetic sensor (1) according to a fifth aspect, which may be implemented in conjunction with the fourth aspect, the distance (L1) is equal to or less than 150 μm.

This aspect contributes to downsizing the magnetic sensor (1).

In a magnetic sensor (1) according to a sixth aspect, which may be implemented in conjunction with any one of the first to fifth aspects, the supporting substrate (11) has a first principal surface (111) and a second principal surface (112) and outer peripheral surfaces (113). The first principal surface (111) and the second principal surface (112) face each other in the thickness direction (D3) defined for the supporting substrate (11). The outer peripheral surfaces (113) are aligned with the thickness direction (D3) defined for the supporting substrate (11) to connect the first principal surface (111) and the second principal surface (112) to each other. The magnetic sensor (1) further includes an electrode (15-17) and a plating layer (18). The electrode (15-17) is electrically connected to the magnetoresistive layer (13) and formed across the first principal surface (111), the outer peripheral surfaces (113), and the second principal surface (112). The plating layer (18) is formed to cover the electrode (15-17).

In a magnetic sensor (1) according to a seventh aspect, which may be implemented in conjunction with the sixth aspect, the plating layer (18) includes: an electroplated copper layer (181); and an electroplated tin layer (182).

This aspect improves electrical connectivity of the magnetic sensor (1) to a mount board on which the magnetic sensor (1) is going to be mounted.

In a magnetic sensor (1) according to an eighth aspect, which may be implemented in conjunction with the sixth aspect, the plating layer (18) includes: an electroplated copper layer (181); and a gold plating layer.

This aspect improves electrical connectivity of the magnetic sensor (1) to a mount board on which the magnetic sensor (1) is going to be mounted.

In a magnetic sensor (1) according to a ninth aspect, which may be implemented in conjunction with the sixth aspect, the plating layer (18) includes: an electroless plated nickel-phosphorus layer; and an electroplated tin layer.

This aspect improves electrical connectivity of the magnetic sensor (1) to a mount board on which the magnetic sensor (1) is going to be mounted.

In a magnetic sensor (1) according to a tenth aspect, which may be implemented in conjunction with the sixth aspect, the plating layer (18) includes: an electroless plated nickel-phosphorus layer; and a gold plating layer.

This aspect improves electrical connectivity of the magnetic sensor (1) to a mount board on which the magnetic sensor (1) is going to be mounted.

In a magnetic sensor (1) according to an eleventh aspect, which may be implemented in conjunction with any one of the sixth to tenth aspects, the electrode (15-17) includes: at least one first metal layer (165) containing either chromium or a chromium alloy; and at least one second metal layer (165) containing either copper or a copper-nickel alloy.

This aspect ensures that the magnetoresistive layer (13) is electrically conductive while increasing the degree of adhesion to underlying members (namely, the supporting substrate 11, the glass glazing layer 12, and the magnetoresistive layer 13).

In a magnetic sensor (1) according to a twelfth aspect, which may be implemented in conjunction with any one of the sixth to tenth aspects, the electrode (15-17) is a metal layer containing either nickel chromium or a nickel chromium alloy.

This aspect ensures that the magnetoresistive layer (13) is electrically conductive while increasing the degree of adhesion to underlying members (namely, the supporting substrate 11, the glass glazing layer 12, and the magnetoresistive layer 13).

In a magnetic sensor (1) according to a thirteenth aspect, which may be implemented in conjunction with any one of the first to twelfth aspects, the magnetoresistive layer (13) includes: a plurality of magnetoresistance pattern portions (131-134); and a plurality of terminal pattern portions (21-24). The plurality of terminal pattern portions (21-24) are arranged to surround the plurality of magnetoresistance pattern portions (131-134). When viewed in plan in the thickness direction (D3) defined for the supporting substrate (11), an outer edge (211-214) of each of the plurality of terminal pattern portions (21-24) is located inside an outer edge (110) of the supporting substrate (11).

This aspect reduces an adverse effect on the magnetoresistive layer (13) when the supporting substrate (11) is cut off.

Note that the constituent elements according to the second to thirteenth aspects are not essential constituent elements for the magnetic sensor (1) but may be omitted as appropriate.

### REFERENCE SIGNS LIST

1 Magnetic Sensor
11 Supporting Substrate
12 Glass Glazing Layer (Glazing Layer)
13 Magnetoresistive Layer
15 Upper Surface Electrode (Electrode)
16 End Face Electrode (Electrode)
17 Lower Surface Electrode (Electrode)
18 Plating Layer
21 Power Supply Terminal (Terminal Pattern Portion)
22 Ground Terminal (Terminal Pattern Portion)
23 First Output Terminal (Terminal Pattern Portion)
24 Second Output Terminal (Terminal Pattern Portion)
110 Outer Edge
111 First Principal Surface
112 Second Principal Surface
113 Outer Peripheral Surface
130 Outer Edge
131-134 Magnetoresistance Pattern Portion
165 First Metal Layer
166 Second Metal Layer
181 Electroplated Copper Layer
182 Electroplated Tin Layer
211, 221, 231, 241 Outer Edge
D3 Third Direction (Thickness Direction)
L1 Distance
T1 Thickness

1. A magnetic sensor comprising:
a supporting substrate;
a glazing layer formed on the supporting substrate; and
a magnetoresistive layer formed on the glazing layer,
an outer edge of the magnetoresistive layer being located, when viewed in plan in a thickness direction defined for the supporting substrate, inside an outer edge of the supporting substrate.

2. The magnetic sensor of claim 1, wherein
a ratio of a distance between the outer edge of the supporting substrate and outer edge of the magnetoresistive layer when viewed in plan in the thickness direction defined for the supporting substrate to a thickness of the glazing layer is equal to or greater than 0.5.

3. The magnetic sensor of claim 2, wherein
the ratio is equal to or less than 3.0.

4. The magnetic sensor of claim 1, wherein
a distance between the outer edge of the supporting substrate and the outer edge of the magnetoresistive layer when viewed in plan in the thickness direction defined for the supporting substrate is equal to or greater than 5 μm.

5. The magnetic sensor of claim 4, wherein
the distance is equal to or less than 150 μm.

6. The magnetic sensor of claim 1, wherein
the supporting substrate has:
a first principal surface and a second principal surface facing each other in the thickness direction defined for the supporting substrate; and
outer peripheral surfaces aligned with the thickness direction defined for the supporting substrate to connect the first principal surface and the second principal surface to each other, and
the magnetic sensor further includes:
an electrode electrically connected to the magnetoresistive layer and formed across the first principal surface, the outer peripheral surfaces, and the second principal surface; and
a plating layer formed to cover the electrode.

7. The magnetic sensor of claim 6, wherein
the plating layer includes:
an electroplated copper layer; and
an electroplated tin layer.

8. The magnetic sensor of claim 6, wherein
the plating layer includes:
an electroplated copper layer; and
a gold plating layer.

9. The magnetic sensor of claim 6, wherein
the plating layer includes:
an electroless plated nickel-phosphorus layer; and
an electroplated tin layer.

10. The magnetic sensor of claim 6, wherein
the plating layer includes:
an electroless plated nickel-phosphorus layer; and
a gold plating layer.

11. The magnetic sensor of claim 6, wherein
the electrode includes:
at least one first metal layer containing either chromium or a chromium alloy; and
at least one second metal layer containing either copper or a copper-nickel alloy.

12. The magnetic sensor of claim 6, wherein
the electrode is a metal layer containing either nickel chromium or a nickel chromium alloy.

13. The magnetic sensor of claim 1, wherein
the magnetoresistive layer includes:
a plurality of magnetoresistance pattern portions; and
a plurality of terminal pattern portions arranged to surround the plurality of magnetoresistance pattern portions, and
an outer edge of each of the plurality of terminal pattern portions is located inside an outer edge of the supporting substrate when viewed in plan in the thickness direction defined for the supporting substrate.
